(19) United States
(12) Patent Application Publication
(10) Pub. No.: US 2002/0122129 A1
(43) Pub. Date: Sep. 5, 2002

(54) CMOS image sensor improving picture quality

(76) Inventor: Do-Young Lee, Ichon-shi (KR)

Correspondence Address: MARSHALL, GERSTEIN & BORUN, 6300 SEARS TOWER, 233 SOUTH WACKER, CHICAGO, IL, 60606-6357, US

(21) Appl. No.: 10/032,639

(22) Filed: Dec. 28, 2001

(30) Foreign Application Priority Data
Dec. 30, 2000 (KR) 2000-86594

(51) Int. Cl. H04N 5/335

(52) U.S. Cl. 348/308; 348/302

(57) ABSTRACT

The disclosed devices provide a CMOS sensor and, more particularly, an enhanced CMOS sensor improving picture quality by concurrently performing a gamma correction and an analog-to-digital conversion. In an embodiment, there is provided a CMOS image sensor, having: an image capturing unit for converting rays of light incident upon a photo-sensitive area to an analog signal; an analog-to-digital converter for converting the analog image signal to a digital image signal; and a ramp signal generator for producing a ramp signal in order to provide a reference voltage signal to the analog-to-digital converter. The ramp signal generator may include: a) a plurality of capacitors and switches; b) an amplifier coupled to the plurality of capacitors and switches for receiving a gain and reset voltage from external circuitry; and c) capacitance controlling means coupled in parallel to at least one capacitor in the ramp signal generator in order to form the ramp signal for an analog gamma correction.

### FIELD OF THE INVENTION

The present invention relates to a CMOS image sensor and, more particularly, to an enhanced CMOS image sensor improving picture quality without quantization noise.

### BACKGROUND OF THE INVENTION

Generally, an image sensor is an image capture device that captures an image, for example, by using the photo-absorption characteristic of semiconductors, i.e., a photon reaction process. All objects in nature have luminance and color, and each pixel of an image sensor converts such photonic information to an electrical signal corresponding to the color and the luminance of the object. The image sensor processes the electrical signal(s) to create a high quality image of the object.

Normally, the image sensor is composed of a pixel array constructed with tens of thousands to hundreds of thousands of unit pixels, an A/D converter for converting an analog voltage to a digital value, and memory units. Some image sensors support a correlated double sampling technique (hereinafter, referred to as “CDS”) in generating the high quality image. CDS is widely known technology.

The image signal generated from the image sensor has to be passed through various steps before a high quality image is generated. The conventional image processing is described in accordance with FIG. 1

FIG. 1 is a flowchart illustrating the conventional image processor connected to a CMOS image sensor. As shown, an analog image signal is received from a pixel array and this is normally converted to an 8-bit digital image signal after the CDS process in the CMOS image sensor. The 8-bit digital image signal is modified using several signal processing steps to achieve better image quality. Gamma correction is one of these processing steps.

Unfortunately, when gamma correction is applied to the digitized image signal generated from the CMOS image sensor, the effective bit resolution of the image data is reduced from the original 8 bits to 5 or 6 bits image resolution.

FIG. 2 is a high-level block diagram illustrating components of a conventional CMOS image sensor. Detailed connections between blocks are omitted in FIG. 2, but would be understood. Both the A/D conversion and the CDS are now explained.

As shown in FIG. 2, an analog-to-digital converter (ADC) is composed of a ramp signal generator 10, a comparator 20, and a memory buffer 30. The ramp signal generator 10 makes a ramp signal, which is used as a reference signal to convert an analog image signal generated from pixel array into a digital value, or a digital image signal. The comparator 20 compares the analog pixel output signal from the pixel array with a reference ramp signal from the ramp signal generator 10. The memory buffer 30 saves the result of the comparison of the pixel output voltage level and the ramping voltage level, which drops little by little by a uniform voltage level at each digital clock pulse.

The ADC performs the analog-to-digital conversion using the following steps: applying the analog image signal from the pixel array to the comparator 20 as an input; applying the ramp signal generated from the ramp signal generator 10 as another input; and saving a clock count value to memory buffer 30, wherein the clock count value is the number of counted clock pulses until the ramping voltage level, which drops each clock pulse, goes through the pixel output voltage level. By way of further background on the analog-to-digital conversion steps, FIG. 3 shows a detailed illustration of how the digital data image may be created.

As mentioned above, it is necessary to have a ramp signal to perform the CDS. FIG. 4 shows a double ramp signal for the CDS, as would be created by the ramp signal generator 10. The ramp signal generator 10 makes a first ramp signal for reading a reset level that represents the initial state of a pixel in the pixel array. A second ramp signal is generated by the ramp signal generator 10 for reading the signal level of the pixel output. The ramp signal generator 10 outputs a linear ramping signal as shown FIG. 4.

Finally, since the gamma correction is performed with the digital data after the analog-to-digital conversion, the original 8-bit image quality is reduced to 6-bit image quality, for example, by the characteristics of the digital gamma correction. This decreases the digital image signal and the image quality of the CMOS image sensor.

### SUMMARY OF THE INVENTION

It is, therefore, desirable to provide an enhanced CMOS image sensor that improves the entire image quality by concurrently performing gamma correction and analog-to-digital conversion of image signals, by modifying the ramp signal.

In accordance with an aspect of the disclosed, there is provided a CMOS image sensor, having: an image capturing unit for converting light incident upon a photo-sensitive area to an analog signal; an analog-to-digital converter for converting the analog image signal to a digital image signal; and a ramp signal generator for producing a ramp signal in order to provide a reference voltage signal to the analog-to-digital converter, the ramp signal generator including: a) a plurality of capacitors and switches; b) an amplifier coupled to the plurality of capacitors and switches for receiving gain and reset voltages from an external circuit; and c) a capacitance controlling unit coupled in parallel to at least one of the plurality of capacitors in the ramp signal generator in order to form the ramp signal for an analog gamma correction. The plurality of switches in the ramp signal generator are selectively operated in response to a control signal from a digital controller in the CMOS image sensor.

### BRIEF DESCRIPTION OF THE DRAWINGS

The above and other objects and features of the disclosed embodiments will become apparent from the following description of the preferred embodiments given in conjunction with the accompanying drawings, in which:

FIG. 1 is a flowchart illustrating image processing steps in a conventional CMOS image sensor;

FIG. 2 is a block diagram illustrating components of a conventional COMS sensor;

FIG. 3 is a circuit level diagram illustrating an analog-to-digital conversion in accordance with FIG. 2;

FIG. 4 is an exemplary diagram illustrating a ramp signal for performing the CDS in the conventional CMOS sensor with a line-based analog to digital converter;

FIG. 5 is a block diagram illustrating an analog-to-digital conversion and a gamma correction of image signals received from pixels in a CMOS image sensor in accordance with an embodiment of the disclosed apparatus;

FIG. 6 is an exemplary diagram illustrating a ramp signal for concurrently performing an analog-to-digital conversion and a gamma correction on image signals received from pixels in the CMOS image sensor in FIG. 5;

FIG. 7 is a detailed diagram of a chopper comparator in accordance with an embodiment of the disclosed apparatus;

FIG. 8 is a schematic diagram of a typical ramp signal generator; and

FIG. 9 is a detailed diagram of the ramp signal generator of FIG. 5 in accordance with the preferred embodiment of the disclosed apparatus.

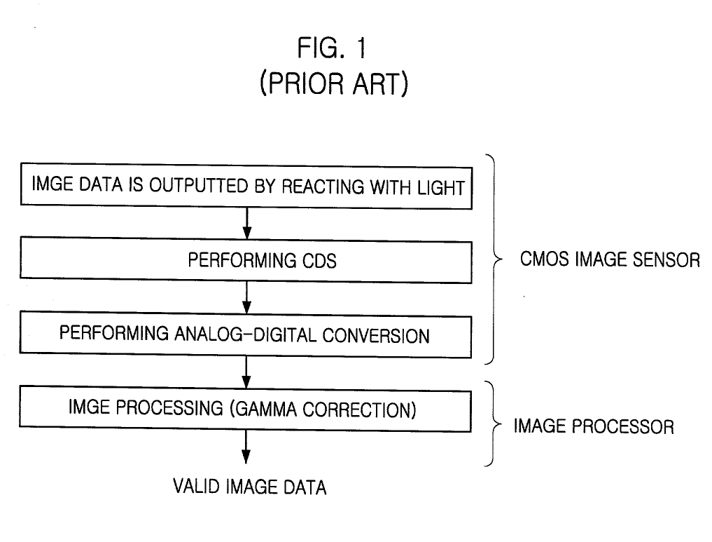

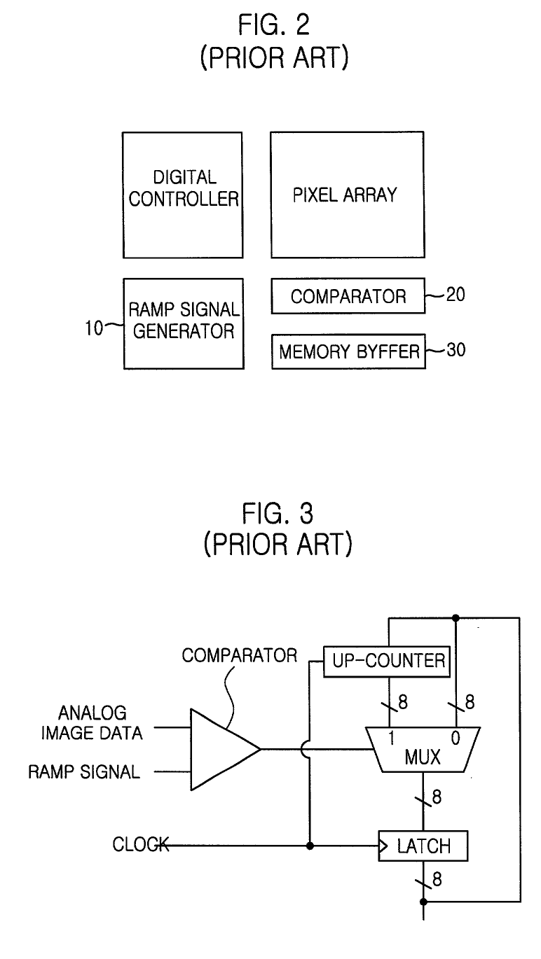

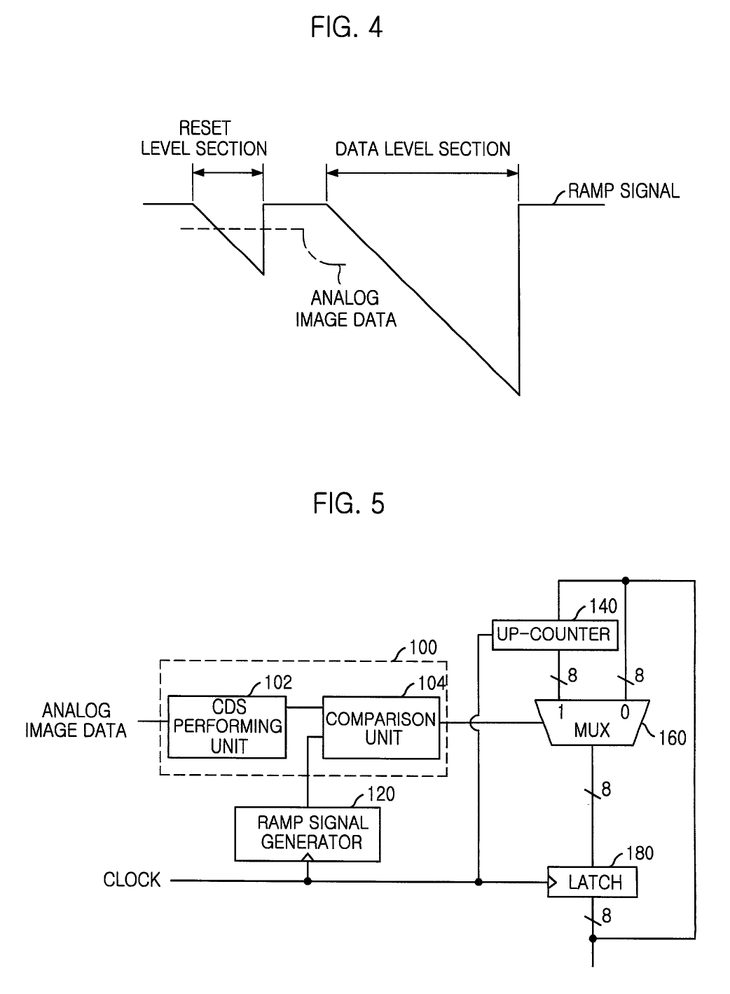

### DETAILED DESCRIPTION OF THE INVENTION

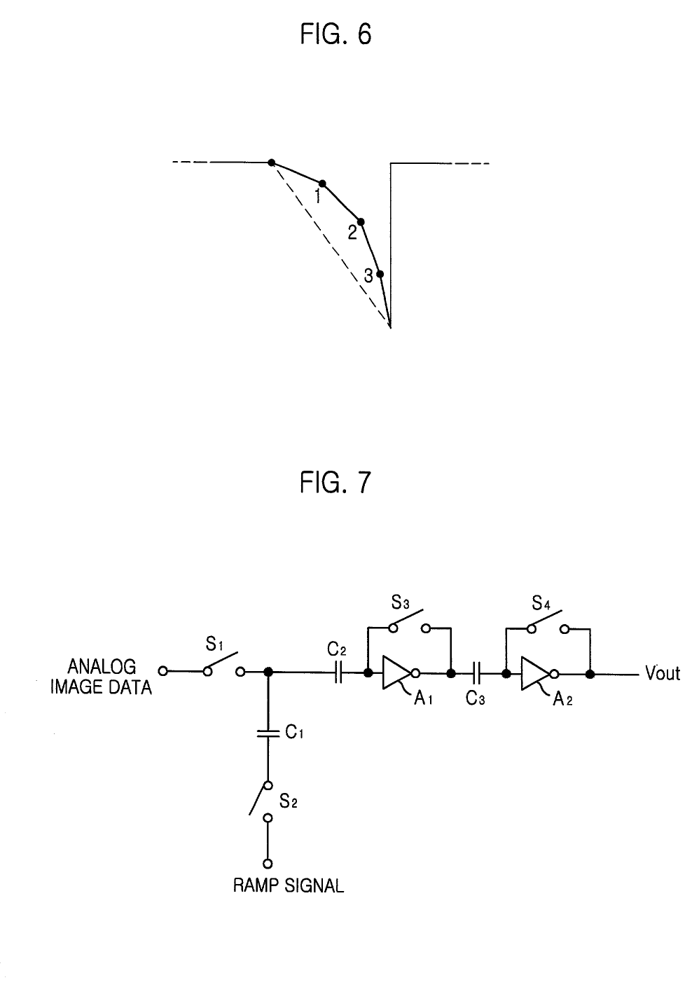

As shown in FIG. 5, a CMOS image sensor has a comparator 100, a ramp signal generator 120, an up-counter (clock pulse counter) 140, a multiplexer 160 and a latch 180. The comparator 100 performs a CDS, an analog-to-digital conversion and a gamma correction of a ramp signal and an analog image signal received from pixels, for example, a pixel array. The ramp signal generator 120 generates a ramp signal, as shown in FIG. 6, in response to an external control signal for the gamma correction and outputs the ramp signal to the comparator 100. The up-counter 140 counts the number of counted clock pulse until the ramping voltage level, which drops in each clock pulse, goes through the pixel output voltage level. The multiplexer 160 selectively outputs a result of the up-counter 140 to an 8-bit latch, in response to an output signal of the comparator 100. The latch 180 saves an output of the multiplexer 160 and feeds a latched value to another multiplexer as an input in response to the clock.

The comparator 100 is composed of the CDS performing unit 102 and a comparison unit 104. The CDS unit 102 performs the CDS on the analog image signal data received from pixels. The comparison unit 104 performs the gamma correction and the analog-to-digital conversion of the analog image signal to a digital image signal after the CDS step. The comparison unit 104 provides the result to the multiplexer 160.

Thus, the analog pixel output signal is connected to the CDS performing unit 102 in the comparator 100, and the CDS step is performed at the analog level, i.e., before the analog-to-digital conversion in the comparison unit 104.

FIG. 7 is a detailed schematic diagram of the comparator 100 for performing the CDS function at an analog level.

In operation, when receiving a reset level value for the CDS, an output signal Vout from the comparator 100 is in a middle voltage level because three switches S₁, S₃, and S₄ are closed, and a switch S₂ is opened. At this point, each device offset voltage is saved in two capacitors C₂ and C₃. Next, the switch S₂ is shorted and a difference between an initial state voltage of the ramp signal generator 120 and the pixel initial output voltage level is saved at a capacitor C₁. The pixel outputs the real image voltage level after the switches S₂, S₃, and S₄ are opened again. Next, the switch S₁ is opened, and then S₂ is closed. At that time, the voltage of the common node of the capacitors C₁ and C₂ shifts by the result voltage of CDS. Finally, the state of the output Vout transits at the time the voltage of the common node of the capacitors C₁ and C₂ reverses to the initial voltage level after the ramp signal generated from the ramp signal generator 120 starts ramping.

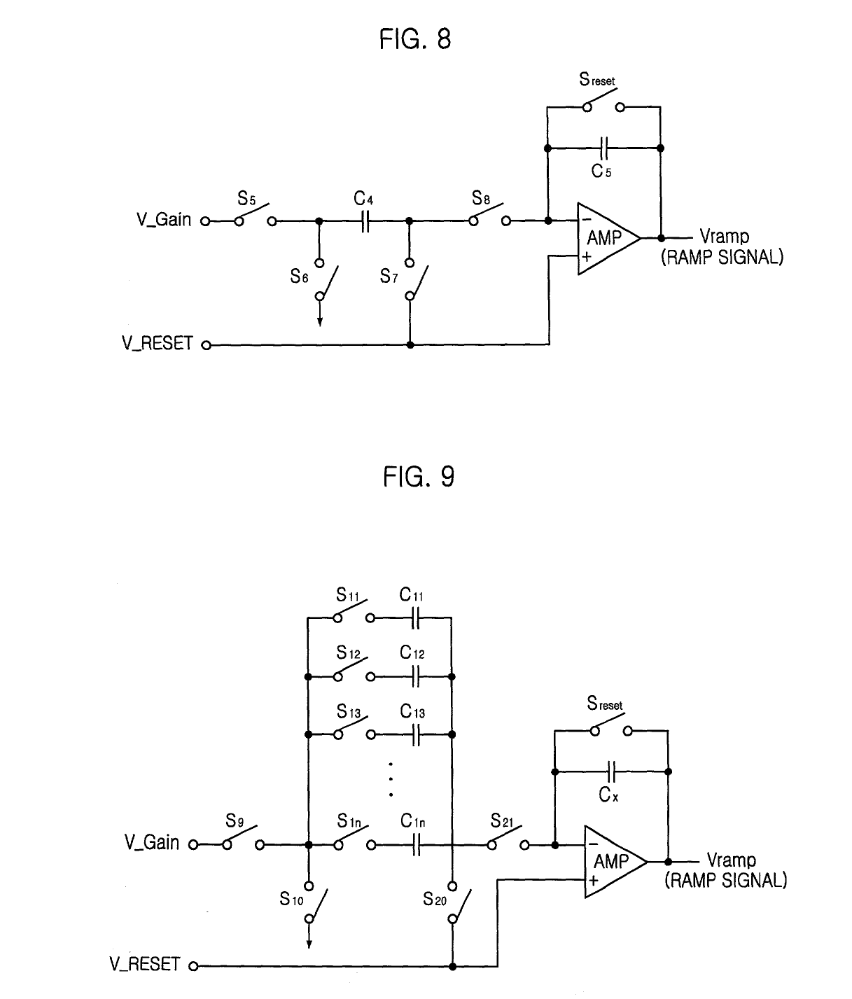

In the meantime, the ramp signal generator 120 has to be designed to represent a gamma curve for simultaneously performing the gamma correction and the analog-to-digital conversion in the comparator 100 of FIG. 5. The size of the step voltage in a ramp signal generator is usually determined by the difference between a gain voltage V₋Gain and a reset voltage V₋RESET , as shown by the ramp signal generator exemplary shown in FIG. 8. Another parameter affecting the unit ramping step voltage in the ramp signal generator circuit of FIG. 8 is the ratio of capacitors C₄ and C₅. The relationship is represented by following equation.

$${V}_{1} step ∝ \frac{{C}_{4}}{{C}_{5}} \qquad Eq . 1$$

FIG. 9 shows the preferred ramp signal generator 120 for generating a ramp signal for concurrently performing the gamma correction and the analog-to-digital conversion in the comparator 100. The ramp signal generator 120 has: a switch S₉, switches S₁₁ to S₁ₙ, capacitors C₁₁ to C₁ₙ, a switch S₁₀, a switch S₂₀, a switch S₂₁, an amplifier AMP, a switch Sᵣₑₛₑₜ, and a capacitor Cₓ. One of two terminals of the switch S₉ is connected to a gain voltage, V₋Gain, and the other is connected to the plurality of switches S₁₁ to S₁ₙ in parallel. The switches S₁₁ to S₁ₙ are connected to the capacitors C₁₁ to C₁ₙ, respectively. The two terminals of the switch S₁₀ are connected to the plurality of the switches S₁₁ to S₁ₙ and to a ground source, respectively. One of two terminals of the switch S₂₀ is commonly connected to the plurality of capacitors C₁₁ to C₁ₙ, and the other is connected to a reset voltage, V₋RESET. The switch S₂₁ is commonly connected to the plurality of capacities C₁₁ to C₁ₙ. A negative input terminal of the AMP is directly connected to the switch S₂₁, and a positive input terminal is connected to the reset voltage, V₋RESET. The AMP outputs a ramp signal Vramp capable of performing a gamma correction in the CDS. A switch Sᵣₑₛₑₜ and a capacitor Cₓ are connected in parallel between the negative input terminal and an output terminal of the AMP.

The ramp signal can be modified based on an amount of a capacitance of the capacitors C₁₁ to C₁ₙ by controlling the switches S₁₁ to S₁ₙ using control signals provided from a digital controller in the CMOS image sensor. Accordingly, modified various ramp signals can be obtained and used to perform a desired gamma correction, because the Eq. 1 may now be expressed as:

$${V}_{1} step ∝ \frac{{C}_{11}}{{C}_{x}} ( \text{when} \text{S} \text{11 is connected} ) \\ {V}_{1} step ∝ \frac{{C}_{12}}{{C}_{x}} ( \text{when} \text{S} \text{12 is connected} ) \\ ⋮ \\ {V}_{1} step ∝ \frac{{C}_{1 n}}{{C}_{x}} ( \text{when} \text{S} \text{1} \text{n} \text{is connected} ) \qquad Eq . 2$$

FIG. 6 shows such a modified ramp signal for the gamma correction where a dotted line represents a normal ramp signal and a solid line represents the modified ramp signal. As is provided, the CMOS image sensor of the disclosed device can simultaneously perform the gamma correction and the analog-to-digital conversion.

As stated above, the enhanced CMOS image sensor of the disclosed device does not decrease the number of valid image bits. Accordingly, the now disclosed devices prevent the decrease of a picture quality caused by conventional gamma correction.

While the present invention has been described with respect to certain preferred embodiments, it will be apparent to those skilled in art that various changes and modifications may be made without departing from the scope of the invention as defined in the following claims.

What is claimed is:

1. A CMOS image sensor, comprising:
an image capturing means for converting light incident upon a photo-sensitive area to an analog image signal;
an analog-to-digital converter for converting the analog image signal to a digital image signal; and
a ramp signal generator for producing a ramp signal in order to provide a reference voltage signal to the analog-to-digital converter, the ramp signal generator including:
a plurality of capacitors and switches;
an amplifier coupled to the plurality of capacitors and switches for receiving gain and reset voltages from external circuitry; and
capacitance controlling means coupled in parallel to at least one of the plurality of capacitors in the ramp signal generator in order to form the ramp signal for an analog gamma correction.

2. The CMOS image sensor as recited in claim 1, wherein the plurality of switches in the ramp signal generator are selectively operated in response to control signals from a digital controller in the CMOS image sensor.

3. The CMOS image sensor as recited in claim 2, wherein the capacitance controlling means includes the plurality of capacitors and the plurality of switches to selectively connect the plurality of capacitors to the amplifier in response to the control signals from the digital controller.

4. The CMOS image sensor as recited in claim 2, further comprising:
counting means for creating a digital counting value based on a result signal from a chopper comparator; and
a latch circuit for storing the digital counting value from the counting means.

5. A CMOS image sensor, comprising:
an image capturing means for capturing an analog image signal from an object;
an analog-to-digital converter to convert the analog image signal to a digital image signal; and
a ramp signal generator producing a ramp signal in order to provide a reference voltage signal to the analog-to-digital converter, said ramp signal generator including:
a first switch connected to a gain voltage;
a plurality of second switches connected in parallel to the first switch;
a plurality of capacitors connected to the second switches;
a third switch connected between the first switch and a ground voltage level;
a fourth switch commonly connected to the plurality of capacitors and connected to a reset voltage;
a fifth switch connected to the plurality of capacitors;
an amplifying means for receiving the reset voltage and receiving the gain voltage via the fifth switch for outputting the ramp signal;
a sixth switch connected in parallel to the amplifying means; and
a capacitor connected in parallel to the sixth switch.

6. The CMOS sensor as recited in claim 5, wherein the plurality of capacitors and the second switches in the ramp signal generator are selectively connected to each other in response to control signals from a digital controller in the CMOS image sensor.
